(19) United States
(12) Patent Application Publication
(10) Pub. No.: US 2026/0311974 A1
(43) Pub. Date: Oct. 8, 2026

(54) SYSTEM AND METHOD TO MAINTAIN CONSTANT CLAMPING PRESSURE DURING CHAMBER REBOOTING AND POWER FAILURE INSTANCES

(71) Applicant: LAM RESEARCH CORPORATION, Fremont, CA (US)

(72) Inventors: Hemanth RAMESH, Bengaluru (IN); Adam Christopher MACE, Morgan Hill, CA (US); Muad M Ahmouda SALEH, Fremont, CA (US)

(21) Appl. No.: 18/998,259

(22) PCT Filed: Jul. 27, 2023
(86) PCT No.: PCT/US2023/028770

§ 371 Date: Jan. 24, 2025

Related U.S. Application Data
(60) Provisional application No. 63/394,795, filed on Aug. 3, 2022.

(51) Int. Cl. H01J 37/32; H10P 72/76

(52) U.S. Cl. CPC H01J 37/32642; H10P 72/7606

(57) ABSTRACT

A clamping system for a substrate support includes a clamping assembly configured to clamp an edge ring to baseplate of the substrate support, a valve control assembly coupled to a compressed air source, and a valve assembly coupled between the valve control assembly and the clamping assembly. The valve assembly is coupled to the compressed air source and the valve control assembly, and the valve assembly separately receives compressed air as inputs from the compressed air source and the valve control assembly. The valve assembly is configured to selectively supply pressurized air from the compressed air source to the clamping assembly to clamp the edge ring to the baseplate in response to the inputs received from the valve control assembly.

### CROSS-REFERENCE TO RELATED APPLICATIONS

This application claims the benefit of U.S. Provisional Application No. filed on 63/394,795, filed on Aug. 3, 2022. The entire disclosure of the above application is incorporated herein by reference.

### FIELD

The present disclosure relates to securing ring structures in substrate processing chambers.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, dielectric etch, and/or other etch, deposition, or cleaning processes. A substrate may be arranged on a substrate support, such as a pedestal, an electrostatic chuck (ESC), etc. in a processing chamber of the substrate processing system. During etching, etch gas mixtures including one or more gases may be introduced into the processing chamber and plasma may be used to initiate chemical reactions.

The substrate support may include a ceramic layer arranged to support a substrate. For example, the substrate may be clamped to the ceramic layer during processing. The substrate support may include an edge ring arranged to surround an outer perimeter of the ceramic layer and the substrate.

### SUMMARY

A clamping system for a substrate support includes a clamping assembly configured to clamp an edge ring to baseplate of the substrate support, a valve control assembly coupled to a compressed air source, and a valve assembly coupled between the valve control assembly and the clamping assembly. The valve assembly is coupled to the compressed air source and the valve control assembly, and the valve assembly separately receives compressed air as inputs from the compressed air source and the valve control assembly. The valve assembly is configured to selectively supply pressurized air from the compressed air source to the clamping assembly to clamp the edge ring to the baseplate in response to the inputs received from the valve control assembly.

In other features, the valve assembly includes a clamp supply port coupled to the compressed air source, a clamp control port coupled to the valve control assembly, a release control port coupled to the valve control assembly, and a release port. The valve assembly has a clamping state and a release state. When in the clamping state, the valve assembly is configured to supply pressurized air from the compressed air source to the clamping assembly and when in the release state, the valve assembly is configured to release pressurized air via the release port. The valve assembly is configured to transition to the clamping state in response to receiving pressurized air from the valve control assembly at the clamp control port. The valve assembly is configured to transition to the clamping state in response to receiving pressurized air from the valve control assembly at the release control port.

In other features, the valve control assembly includes a first solenoid valve coupled between the compressed air source and the clamp control port and a second solenoid valve coupled between the compressed air source and the release control port. To transition the valve assembly to the clamping state, the first solenoid valve is powered and the second solenoid valve is not powered. To transition the valve assembly to the release state, the second solenoid valve is powered and the first solenoid valve is not powered. When the valve assembly is in the clamping state, loss of power to the first solenoid valve and the second solenoid valve does not transition the valve assembly out of the clamping state. When the valve assembly is in the release state, loss of power to the first solenoid valve and the second solenoid valve does not transition the valve assembly out of the release state.

In other features, the valve assembly is an air controlled valve. The clamping assembly includes a plurality of clamping mechanisms mechanically coupled to a support ring of the substrate support, and wherein the edge ring is attached to the support ring. The plurality of clamping mechanisms comprises a plurality of actuators configured to actuate respective rods coupled to the support ring. The actuators are configured to pull down the rods when the clamping assembly receives pressurized air from the valve assembly.

A clamping system configured to clamp an edge ring to a baseplate of a substrate support includes a plurality of clamping mechanisms configured to pull the edge ring downward to clamp the edge ring to the baseplate. A valve assembly is configured to separately receive at a first port, pressurized air from a compressed air source and at second and third ports, pressurized air from a valve control assembly, and to transition between a clamping state and a release state in response to the pressured air received at the second and third ports. When in the clamping state, the valve assembly is configured to supply pressurized air to the plurality of clamping mechanisms and, when in the release state, the valve assembly is configured to release pressurized air via a fourth port.

In other features, the valve assembly is an air controlled valve. The clamping system further includes the valve control assembly. The valve control assembly includes an array of solenoid valves. The array of solenoid valves includes a first solenoid valve coupled between the compressed air source and the second port and a second solenoid valve coupled between the compressed air source and the third port. The first solenoid valve is configured to supply pressurized air from the compressed air source to the second port in response to receiving power from a power source and the second solenoid valve is configured to supply pressurized air from the compressed air source to the third port in response to receiving power from the power source.

In other features, when in the clamping state, the valve assembly is configured to supply pressurized air received at the first port from the compressed air source to plurality of clamping mechanisms regardless of whether the first solenoid valve is receiving power from the power source. When in the release state, the valve assembly is configured to release pressurized air via the fourth port regardless of whether the second solenoid valve is receiving power from the power source.

A clamping system configured to clamp an edge ring to a baseplate of a substrate support includes a plurality of actuators to pull down respective rods to clamp the edge ring to the baseplate, a first solenoid valve coupled between a compressed air source and the plurality of actuators, a second solenoid valve coupled between the compressed air source and the plurality of actuators, and an air controlled valve coupled between the compressed air source and the plurality of actuators and between the first and second solenoid valves and the plurality of actuators. The air controlled valve includes a first port to receive pressurized air from the compressed air source separately from the first and second solenoid valves, a second port to receive pressurized air from the first solenoid valve, and a third port to receive pressurized air from the second solenoid valve.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example substrate processing system according to the present disclosure;

FIG. 2A is an example substrate support and clamping system according to the present disclosure;

FIG. 2B is an example clamping system according to the present disclosure; and

FIG. 3 illustrates respective states of the clamping system during clamping and release operations according to the present disclosure.

In the drawings, reference numbers may be reused to identify similar and/or identical elements.

### DETAILED DESCRIPTION

In a substrate processing chamber, a temperature of an edge ring affects processing parameters such as etch rate and uniformity at an outer edge of a substrate. The edge ring is exposed to the processing environment (including plasma) and absorbs heat. Accordingly, the temperature of the edge ring varies during processing and controlling the temperature of the edge ring helps achieve a repeatable etch rate and process uniformity.

In some examples, the edge ring is arranged in thermal contact with a baseplate or lower ring of the substrate support. Structures such as the baseplate and other ring structures may function as a heat sink for the edge ring. Heat is transferred via an interface between the edge ring and the other structures. In some examples, a thermal interface material (e.g., a silicone-based material such as a gel, paste, pad, etc.) is provided between the edge ring and the baseplate to facilitate transfer of heat from the edge ring to the baseplate.

In some examples, a portion of the edge ring is supported on and/or attached to a support ring, such as a tunable edge sheath (TES) ring. For example, the edge ring is attached to the TES ring using screws or other fasteners. During processing, the TES ring is pulled downward, which in turn pulls the edge ring downward to ensure thermal contact and heat transfer between the edge ring and the thermal interface material. In some examples, the substrate support implements a hold down rod mechanism or system configured to pull the TES ring downward. An example hold down rod system for a TES ring is described in more detail in U.S. Patent Publication No. 2020/0365378, filed on Dec. 15, 2017, the entire contents of which are incorporated herein.

As one example, the hold down rod system includes a bank of solenoid valves configured to selectively pressurize clamp lines coupled to a clamping system (e.g., a plurality of pneumatic actuators). When the clamp lines are pressurized, the pneumatic actuators pull down respective rods to pull down (i.e., clamp) the TES ring and the edge ring. However, the solenoid valves may be deactivated in some situations, such as during a power down or reboot of the substrate processing system, a power failure or other event that interrupts power to the solenoid valves, etc. Deactivation of the solenoid valves unclamps the TES ring, which reduces thermal contact between the edge ring and the baseplate.

Support ring clamping systems and methods according to the present disclosure are configured to maintain clamping pressure during system rebooting and other power interruptions. For example, an air controlled valve assembly is coupled between the solenoid valves and the clamping mechanisms. The valve assembly is configured to maintain a supply of clamping pressure to the clamping mechanisms during reboot or loss of power.

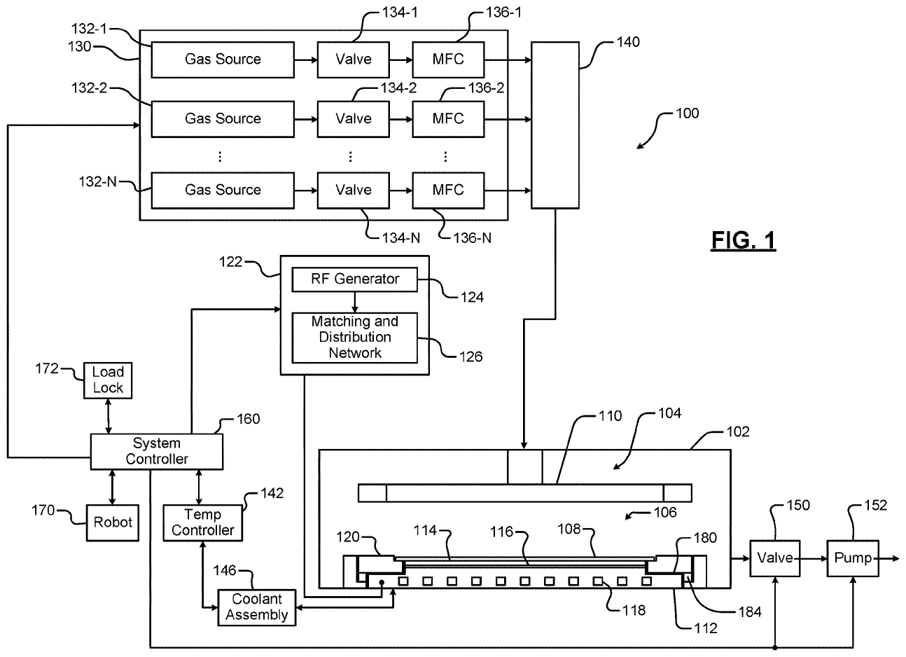

Referring now to FIG. 1, an example substrate processing system 100 is shown. For example only, the substrate processing system 100 may be used for performing etching using RF plasma and/or other suitable substrate processing. The substrate processing system 100 includes a processing chamber 102 that encloses other components of the substrate processing system 100 and contains the RF plasma. The substrate processing chamber 102 includes an upper electrode 104 and a substrate support 106, such as an ESC. During operation, a substrate 108 is arranged on the substrate support 106. While a specific substrate processing system 100 and processing chamber 102 are shown as an example, the principles of the present disclosure may be applied to other types of substrate processing systems and processing chambers, such as a substrate processing system that generates plasma in-situ, implements remote plasma generation and delivery (e.g., using a plasma tube, a microwave tube), etc.

For example only, the upper electrode 104 may include a gas distribution device such as a showerhead 110 that introduces and distributes process gases. The showerhead 110 may include a stem portion including one end connected to a top surface of the processing chamber 102. A base portion is generally cylindrical and extends radially outwardly from an opposite end of the stem portion at a location that is spaced from the top surface of the processing chamber. A substrate-facing surface or faceplate of the base portion of the showerhead 110 includes a plurality of holes through which process gas or purge gas flows. Alternately, the upper electrode 104 may include a conducting plate and the process gases may be introduced in another manner.

The substrate support 106 includes a conductive baseplate 112 that acts as a lower electrode. The baseplate 112 supports a ceramic layer 114. A bond layer (e.g., an adhesive and/or thermal bond layer) 116 may be arranged between the ceramic layer 114 and the baseplate 112. The baseplate 112 may include one or more coolant channels 118 for flowing coolant through the baseplate 112. The substrate support 106 may include an edge ring 120 arranged to surround an outer perimeter of the substrate 108.

An RF generating system 122 generates and outputs an RF voltage to one of the upper electrode 104 and the lower electrode (e.g., the baseplate 112 of the substrate support 106). The other one of the upper electrode 104 and the baseplate 112 may be DC grounded, AC grounded or floating. In the present example, the RF voltage is supplied to the lower electrode. For example only, the RF generating system 122 may include an RF voltage generator 124 that generates the RF voltage that is fed by a matching and distribution network 126 to the upper electrode 104 or the baseplate 112. In other examples, the plasma may be generated inductively or remotely. Although, as shown for example purposes, the RF generating system 122 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more etch gases and mixtures thereof. The gas sources may also supply carrier and/or purge gas. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 110.

A temperature controller 142 may communicate with a coolant assembly 146 to control coolant flow through the channels 118. For example, the coolant assembly 146 may include a coolant pump and reservoir. The temperature controller 142 operates the coolant assembly 146 to selectively flow the coolant through the channels 118 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160.

A thermal interface 180 is defined between the edge ring 120 and an upper surface of the baseplate 112. For example, the edge ring 120 may contact and be supported on the upper surface of the baseplate 112. A thermal interface material (e.g., a silicone-based material such as a gel, paste, pad, etc., not shown in FIG. 1) is provided in the thermal interface 180 between the edge ring 120 and the baseplate 112. The thermal interface material facilitates cooling of the edge ring 120 (i.e., heat transfer from the edge ring 120 to baseplate 112).

The edge ring 120 is at least partially supported on and/or in contact with a support ring 184, such as a TES ring. For example, the edge ring 120 is attached to the support ring 184 using screws or other fasteners. The support ring 184 is pulled downward (e.g., using a clamping system as described below in more detail) to clamp the edge ring 120 against the baseplate 112. In this manner, thermal contact between the edge ring 120 and the baseplate 112 is maximized.

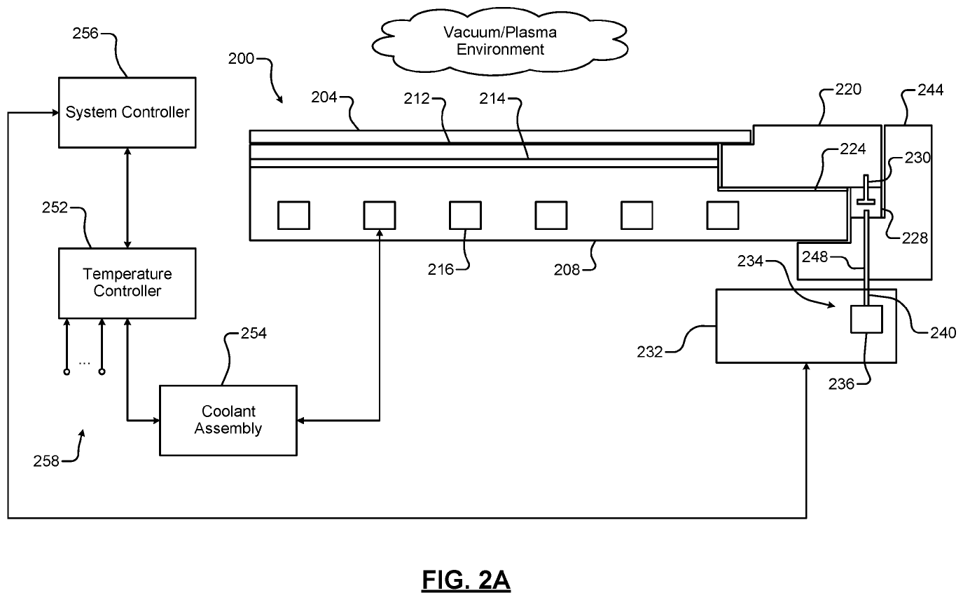

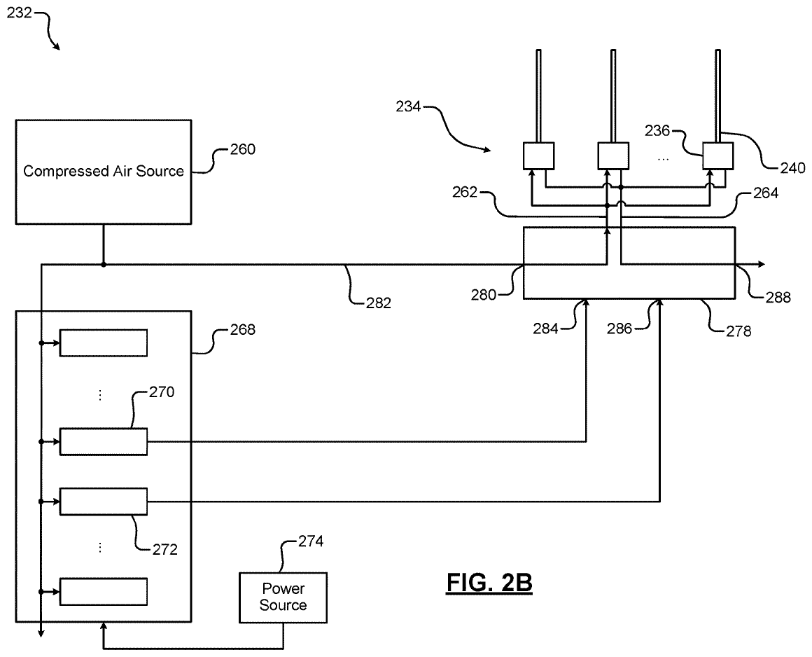

Referring now to FIG. 2A, a portion of an example substrate support 200 according to the present disclosure is shown. The substrate support 200 is configured to support a substrate 204. The substrate support 200 includes a baseplate (e.g., a conductive baseplate) 208, a ceramic layer 212, and, in some examples, a bond layer 214 arranged between the ceramic layer 212 and the baseplate 208. The baseplate 208 may include one or more coolant channels 216 for flowing coolant through the baseplate 208. The substrate support 200 includes an edge ring 220 arranged to surround an outer perimeter of the substrate 204. A thermal interface material 224 is disposed between the edge ring 220 and the baseplate 208 (e.g., adjacent to a backside of the edge ring 220). The thermal interface material 224 facilitates cooling of the edge ring 120.

The edge ring 220 is at least partially supported on and/or in contact with a support ring 228. For example, the edge ring 220 is attached to the support ring 228 using fasteners, such as screws 230. Although the edge ring 220 and the support ring 228 are shown as separate components, in other examples the edge ring 220 and the support ring 228 may comprise a single, integrated component. The support ring 228 is pulled downward to clamp the edge ring 220 against the baseplate 208. For example, a clamping system 232 includes a clamping assembly 234. The clamping assembly 234 includes one or more clamping mechanisms, such as pneumatic linear actuators 236. The actuators 236 are configured to pull respective hold down rods 240 downward, which in turn pulls the support ring 228 and the edge ring 220 downward. For example, the support ring 228 may be arranged on an outer ring 244 (e.g., a ring comprising quartz or another insulative material). The rods 240 extend through channels 248 defined in the outer ring 244 and into the support ring 228.

A temperature controller 252 communicates with a coolant assembly 254 to control coolant flow through the channels 216. The temperature controller 252 may also operate the coolant assembly 254 to selectively flow the coolant through the channels 216 to cool the substrate support 200. The temperature controller 252 may be a separate controller, implemented within a system controller 256, etc. The temperature controller 252 may be configured to measure and/or calculate a temperature of the edge ring 220 based in part on sensed and/or modeled temperatures of the substrate support 200 and the edge ring 220, process parameters, etc.

For example, the temperature controller 252 determines the temperature of the edge ring 220 in accordance with temperatures of the substrate support 200 and the edge ring 220 as measured using one or more temperature sensors (not shown). In other examples, the temperature controller 252 may be configured to calculate the temperature of the edge ring 220 using other measured and/or estimated values, such as an output of a model. For example, the temperature controller 252 may receive one or more signals 258 corresponding to directly sensed temperatures and/or other process parameters used to calculate the temperature of the edge ring 220.

Referring now to FIG. 2B and with continued reference to FIG. 2A, an example of the clamping system 232 according to the present disclosure is shown in more detail. The clamping system 232 includes clamping assembly 234. In this example, the clamping assembly 234 includes a plurality of clamping mechanisms, such as the actuators 236 and respective hold down rods 240. Clamping pressure is supplied to the actuators 236 from a compressed air source 260 via one or more pressurized clamp lines 262 to pull down the rods 240 and clamp the edge ring 220 to the baseplate 208. For example, the compressed air source 260 may include multiple compressed air sources, air compressors, etc. Conversely, pressure is released from the actuators 236 to release the edge ring 220 via one or more release lines 264.

A valve control assembly, such as a solenoid valve bank or array 268, is coupled between the compressed air source 260 and the actuators 236. The solenoid valve array 268 is configured to selectively pressurize the clamp lines 262 to clamp the edge ring 220 and release pressure from the actuators 236 to release the edge ring 220. For example, a first solenoid valve 270 coupled to the compressed air source 260 is configured to be selectively opened to pressurize the clamp lines 262. Conversely, a second solenoid valve 272 is configured to be selectively opened to release pressure from the actuators 236. In other words, during processing, power is supplied (e.g., from a power source 274 responsive to system controller 160) to open the first solenoid valve 270 to clamp the edge ring 220 while power is supplied to open the second solenoid valve 272 to release the edge ring 220.

Power supplied to the solenoid valve array 268 may be interrupted in some situations, such as during a power down or reboot of the substrate processing system 100, a power failure or other event that interrupts power to the solenoid valve array 268, etc. Interrupting power supplied to the solenoid valve array 268 during processing deactivates the solenoid valve 270, which unclamps the edge ring 220 and reduces thermal contact between the edge ring 220 and the baseplate 208.

The clamping system 232 according to the present disclosure is configured to maintain a desired clamping or release state of the actuators 236 and the edge ring 220 during system rebooting and other power interruptions. For example, an air controlled valve assembly (e.g., a multi-port valve) 278 is coupled between the solenoid valves 270, 272 and the actuators 236. The valve assembly 278 is configured to maintain a supply of clamping pressure to the actuators 236 during reboot or loss of power as described below in more detail.

As shown, a first port (e.g., a clamp supply port) 280 of the valve assembly 278 is coupled to the compressed air source 260 via a direct clamp line 282. Accordingly, the valve assembly 278 directly receives compressed air as an input from the compressed air source 260. A path between the compressed air source 260 and the clamp supply port 280 does not include a solenoid valve. In other words, the valve assembly 278 is coupled to the compressed air source 260 separately from the solenoid valve array 268, and therefore is configured to receive a pressured supply of air from the compressed air source 260 regardless of whether a solenoid valve coupled to the clamp supply port 280 is supplied with power. Accordingly, interrupting power to the solenoid valve array 268 does not interrupt the supply of pressurized air to the clamp supply port 280.

Conversely, the first solenoid valve 270 is coupled to a second port (e.g., a clamp control port 284) of the valve assembly 278 while the second solenoid valve 272 is coupled to a third port (e.g., a release control port) 286 of the valve assembly 278. Accordingly, the valve assembly 278 receives compressed air as inputs from the first solenoid valve 270 and the second solenoid valve 272. Since the valve assembly 278 is air controlled, supply of pressured air to the clamp control port 284 or the release control port 286 transitions the valve assembly 278 between first and second positions or states. In a first (e.g., clamping) state, the clamp control port 284 is pressurized and the valve assembly 278 supplies the pressurized air from the direct clamp line 280 to the actuators 236. In other words, when the first solenoid valve 270 is powered (i.e., on) and the second solenoid valve 272 is not powered (i.e., off), the valve assembly 278 is in the clamping state.

Further, when the valve assembly 278 is in the clamping state, interruption of power supplied to the first solenoid valve 270 does not interrupt the supply of clamping pressure to the actuators 236. For example, since a loss of power to the solenoid valve array 268 interrupts power supplied to both the first solenoid valve 270 and the second solenoid valve 272, the state of the valve assembly 278 prior to loss of power (i.e., the clamping state) is retained. Accordingly, the valve assembly 278 continues to receive pressurized air from the compressed air source 260 via the direct clamp line 282 and the edge ring 220 remains clamped during system rebooting or other power failures.

In a second (e.g., release) state, the release control port 286 is pressurized and the valve assembly 278 releases the pressurized air via a fourth port (e.g., a release port) 288. In other words, when the second solenoid valve 272 is powered (i.e., on) and the first solenoid valve 270 is not powered (i.e., off), the valve assembly 278 is in the release state.

When the valve assembly 278 is in the release state, interruption of power supplied to the second solenoid valve 272 does not interrupt the release state of the valve assembly 278. For example, since a loss of power to the solenoid valve array 268 interrupts power supplied to both the first solenoid valve 270 and the second solenoid valve 272, the state of the valve assembly 278 prior to loss of power (i.e., the release state) is retained. Accordingly, the valve assembly 278 continues release pressurized air via the release port 288 and the edge ring 220 remains released during system rebooting or other power failures.

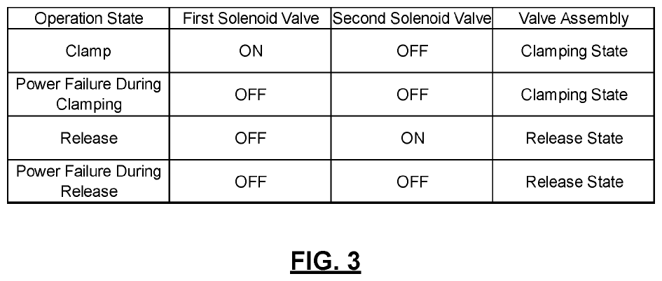

FIG. 3 is a table 300 illustrating respective states of the first solenoid valve 270, the second solenoid valve 272, and the valve assembly 278 of the clamping system 232 during clamping and release operations according to the present disclosure. In a clamp state, the edge ring 220 is clamped to the baseplate 208. Accordingly, the first solenoid valve 270 is ON (i.e., powered or energized to open the first solenoid valve 270), the second solenoid valve 272 is OFF (i.e., not receiving power), and the valve assembly 278 is in the clamping state. In a power failure state that occurs during clamping, both the first solenoid valve 270 and the second solenoid valve 272 are OFF (i.e., not supplied with power). However, the valve assembly 278 retains the clamping state and continues to supply pressurized air from the compressed air source 260 to the actuators 236.

In a release state, the first solenoid valve 270 is OFF, the second solenoid valve 272 is ON, and the valve assembly 278 is in the release state. Accordingly, the valve assembly 278 is in a configuration such that pressured air is released via the release port 288. In a power failure state that occurs during release, both the first solenoid valve 270 and the second solenoid valve 272 are OFF (i.e., not supplied with power). However, the valve assembly 278 retains the release state.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A clamping system for a substrate support, the clamping system comprising:
a clamping assembly configured to clamp an edge ring to baseplate of the substrate support;
a valve control assembly coupled to a compressed air source; and
a valve assembly coupled between the valve control assembly and the clamping assembly, wherein (i) the valve assembly is coupled to the compressed air source and the valve control assembly and (ii) the valve assembly separately receives compressed air as inputs from the compressed air source and the valve control assembly, wherein
the valve assembly is configured to selectively supply pressurized air from the compressed air source to the clamping assembly to clamp the edge ring to the baseplate in response to the inputs received from the valve control assembly.

2. The clamping system of claim 1, wherein the valve assembly includes a clamp supply port coupled to the compressed air source, a clamp control port coupled to the valve control assembly, a release control port coupled to the valve control assembly, and a release port.

3. The clamping system of claim 2, wherein (i) the valve assembly has a clamping state and a release state, (ii) when in the clamping state, the valve assembly is configured to supply pressurized air from the compressed air source to the clamping assembly, and (iii) when in the release state, the valve assembly is configured to release pressurized air via the release port.

4. The clamping system of claim 3, wherein (i) the valve assembly is configured to transition to the clamping state in response to receiving pressurized air from the valve control assembly at the clamp control port and (ii) the valve assembly is configured to transition to the clamping state in response to receiving pressurized air from the valve control assembly at the release control port.

5. The clamping system of claim 4, wherein the valve control assembly includes (i) a first solenoid valve coupled between the compressed air source and the clamp control port and (ii) a second solenoid valve coupled between the compressed air source and the release control port.

6. The clamping system of claim 5, wherein (i) to transition the valve assembly to the clamping state, the first solenoid valve is powered and the second solenoid valve is not powered and (ii) to transition the valve assembly to the release state, the second solenoid valve is powered and the first solenoid valve is not powered.

7. The clamping system of claim 6, wherein, when the valve assembly is in the clamping state, loss of power to the first solenoid valve and the second solenoid valve does not transition the valve assembly out of the clamping state.

8. The clamping system of claim 7, wherein, when the valve assembly is in the release state, loss of power to the first solenoid valve and the second solenoid valve does not transition the valve assembly out of the release state.

9. The clamping system of claim 1, wherein the valve assembly is an air controlled valve.

10. The clamping system of claim 1, wherein the clamping assembly includes a plurality of clamping mechanisms mechanically coupled to a support ring of the substrate support, and wherein the edge ring is attached to the support ring.

11. The clamping system of claim 10, wherein the plurality of clamping mechanisms comprises a plurality of actuators configured to actuate respective rods coupled to the support ring.

12. The clamping system of claim 11, wherein the actuators are configured to pull down the rods when the clamping assembly receives pressurized air from the valve assembly.

13. A clamping system configured to clamp an edge ring to a baseplate of a substrate support, the clamping system comprising:
a plurality of clamping mechanisms configured to pull the edge ring downward to clamp the edge ring to the baseplate; and
a valve assembly configured to
separately receive (i) at a first port, pressurized air from a compressed air source and (ii) at second and third ports, pressurized air from a valve control assembly, and
transition between a clamping state and a release state in response to the pressured air received at the second and third ports,
wherein, when in the clamping state, the valve assembly is configured to supply pressurized air to the plurality of clamping mechanisms and, when in the release state, the valve assembly is configured to release pressurized air via a fourth port.

14. The clamping system of claim 13, wherein the valve assembly is an air controlled valve.

15. The clamping system of claim 13, further comprising the valve control assembly, wherein the valve control assembly includes an array of solenoid valves.

16. The clamping system of claim 15, wherein the array of solenoid valves includes (i) a first solenoid valve coupled between the compressed air source and the second port and (ii) a second solenoid valve coupled between the compressed air source and the third port.

17. The clamping system of claim 16, wherein (i) the first solenoid valve is configured to supply pressurized air from the compressed air source to the second port in response to receiving power from a power source and (ii) the second solenoid valve is configured to supply pressurized air from the compressed air source to the third port in response to receiving power from the power source.

18. The clamping system of claim 17, wherein, when in the clamping state, the valve assembly is configured to supply pressurized air received at the first port from the compressed air source to plurality of clamping mechanisms regardless of whether the first solenoid valve is receiving power from the power source.

19. The clamping system of claim 18, wherein, when in the release state, the valve assembly is configured to release pressurized air via the fourth port regardless of whether the second solenoid valve is receiving power from the power source.

20. A clamping system configured to clamp an edge ring to a baseplate of a substrate support, the clamping system comprising:
a plurality of actuators to pull down respective rods to clamp the edge ring to the baseplate;
a first solenoid valve coupled between a compressed air source and the plurality of actuators;
a second solenoid valve coupled between the compressed air source and the plurality of actuators; and
an air controlled valve coupled (i) between the compressed air source and the plurality of actuators and (ii) between the first and second solenoid valves and the plurality of actuators, wherein the air controlled valve includes
a first port to receive pressurized air from the compressed air source separately from the first and second solenoid valves,
a second port to receive pressurized air from the first solenoid valve, and
a third port to receive pressurized air from the second solenoid valve.
